(19) United States
(12) Patent Application Publication
(10) Pub. No.: US 2022/0232720 A1
(43) Pub. Date: Jul. 21, 2022

(54) INTEGRATIVE ARCHITECTURE FOR MODULAR ELECTRICAL UTILIZATION

(71) Applicants: Benjamin GUTIERREZ, (US); Cameron SACKS, (US)

(72) Inventors: Benjamin GUTIERREZ, San Diego, CA (US); Cameron SACKS, San Diego, CA (US)

(21) Appl. No.: 17/576,883

(22) Filed: Jan. 14, 2022

Related U.S. Application Data
(60) Provisional application No. 63/138,082, filed on Jan. 15, 2021.

(51) Int. Cl. H05K 7/02; H05K 7/10; H02J 3/38

(52) U.S. Cl. CPC H05K 7/026; H02J 2300/24; H02J 3/381; H05K 7/10

(57) ABSTRACT

The present disclosure relates to an architecture for modular electricity utilization. The modular electrical utility systems may perform storage, conversion, and/or distribution of electrical energy. Related systems and methods are also disclosed.

### BACKGROUND

As we transition towards a sustainable future, the need for energy storage becomes increasingly apparent. Currently, many solutions for energy storage systems have fixed capacities. These systems are adequate when the applications have a fixed requirement for energy storage and power output, however as the need for energy storage grows, so will the diversity of its applications, and when the electrical needs of an application are variable, a modular energy utilization system that can be stacked together to meet this varying demand is necessary. Thus, fixed systems will be too rigid to meet the requirements of each application and as a result, modular energy utilization systems will gain appreciation.

For applications which utilize electrical energy, such as energy storage and photovoltaic farms, current modular approaches benefit these niche applications but hinder their utility when integrated to form a larger system.

### BRIEF SUMMARY

In an aspect, an architecture for modular electricity utilization is provided. The architecture for modular electricity utilization includes one or more modules, wherein each module facilitates a compute process.

In some embodiments, the one or more modules further includes an electrical energy conversion process, an electrical energy distribution process, an energy storage process, or a combination thereof. In some embodiments, each of the one or more modules further includes an interface to an interconnect. In some embodiments, each module of the one or more modules further includes the ability to communicate information pertaining to the internal state of the module. In some embodiments, the one or more modules further includes: the ability to use any electrical power source or electrical power generating device; the ability to use any energy storage device or energy storage mechanism; the ability to provide alternating current (AC) power signals, direct current (DC) power signals, or a combination of AC and DC power signals. In some embodiments, each of the one or more modules further includes: built-in peripheral devices, the ability to interface with wired and/or wireless peripheral devices, or a combination thereof.

In another, interrelated aspect, a system of modular electricity utilization is provided. The system includes one or more modules, connected by at least one interconnect, wherein each module facilitates a compute process.

In some embodiments, the one or more modules further includes an electrical energy conversion process, an electrical energy distribution process, an energy storage process, or a combination thereof. In some embodiments, each module of the one or more modules further includes the ability to communicate information pertaining to the internal state of the module; and wherein each module of the one or more modules further includes the ability to communicate information pertaining to the state of the system. In some embodiments, the system further includes: the ability to use any electrical power source or electrical power generating device; the ability to use any energy storage device or energy storage mechanism; the ability to provide alternating current (AC) power signals, direct current (DC) power signals, or a combination of AC and DC power signals.

In another, interrelated aspect, a method of electrical power utilization is provided. The method includes: connecting two or more modules via an interconnect to form a system of modules; connecting the system of modules to an electrical power source or electrical power generating device; connecting the system of modules to an energy storage device or energy storage mechanism; connecting the system of modules to a load, appliance or power sink which utilizes alternating current (AC) power signals, direct current (DC) power signals, or a combination of AC and DC power signals; connecting the system of modules to wired and/or wireless peripheral devices which include a user interface; monitoring and/or controlling the system state and/or the internal state of each of the two or more modules via the peripheral devices.

In some embodiments, the method further includes an interconnect which provides structural support and/or a mounting mechanism for the two or more modules. In some embodiments, the method further includes built-in peripheral devices to enhance user interface and aid deployment of various system applications. In some embodiments, the method further includes a communication protocol, a state machine, a control technique, data transfer, or a combination thereof, performed via the interconnect. In some embodiments, the communication protocol, state machine, control technique, data transfer, or combination thereof has no designated master. In some embodiments, the method further includes a process in which each module of the two or more modules shares its internal state with other modules via the interconnect; and wherein each module of the two or more modules may be added, removed, or experience a fault condition at any point during this process.

### BRIEF DESCRIPTION OF THE DRAWINGS

FIG. 1 illustrates an overview of each of the eight modules present in the Integrative Architecture for Modular Electrical Utilization (IAMEU). Specifically, this chart depicts which process devices are present within each module disclosed herein. Furthermore, this chart provides the symbol name associated each module disclosed herein.

FIG. 2 illustrates the layout for each of the eight module types disclosed herein, including what processes are contained within each of the eight modules. The numeral 1 marks the required interconnect. The numeral 2 marks the conceptual boundary of the module. The letters a, b, c, and d denote the compute, conversion, distribution and energy storage processes, respectively. Furthermore, each module contains its corresponding symbol name.

FIGS. 3A-3C illustrate embodiments of the interconnects disclosed herein. In these images, the numeral 1 marks the shared data interconnect. Symbols M1, M2 and Mn denote the first, second and nth module present within the system. The letters a, b, c, and d denote the compute, conversion, distribution and energy storage processes, respectively. FIG. 3A illustrates a system configuration in which no shared power busses exist between the modules in the system. FIG. 3B illustrates a system in which all modules share both a data interconnect, and a shared power interconnect marked by the numeral 2. FIG. 3C illustrates a system of four modules in which there are two subgroups of electrically connected modules. The numeral 2 marks the power interconnect shared between modules M1 and M2. The numeral 3 marks the power interconnect shared between modules M3 and M4.

FIG. 4 illustrates an embodiment of the data interconnect required for the proposed “Masterless System Synchronization” or MaSS Protocol. In this image, each module's communication center is referred to as a node. Each line present between each node represents a data interconnect. In this configuration there exists five main functional units: a transmit right and a receive right, a transmit left and a receive left, as well as a shared transmit/receive line.

FIG. 5 is an overview of the IDLE, COUNTOFF, and SYNC phases of the MaSS Protocol. For simplicity, this overview considers how the protocol would perform in a case in which there are only three nodes present. During the IDLE phase, each module recognizes its neighbors, then begins the COUNTOFF phase once all nodes are present. This phase ends with the rightmost node providing the total node count, n, to the rest of the nodes. Then begins the synchronization of system information during the SYNC phase of the protocol.

FIG. 6 illustrates a system application embodiment of an electric car. This embodiment employs certain process-configuration of the pC module as a motor drive for each of the four motors in the vehicle. A process configuration of thepE module is used as the main energy storage mechanism for the vehicle. A process configuration of the pCD module acts as the vehicle's charger. Finally, a process-configuration of a pC module is used as the main interface between the system and the vehicles peripheral devices. In this figure, the solid lines represent the power interconnects, the double line represents the data interconnect, and the dotted double line represents the interconnect between the peripheral devices and the system.

FIG. 7 illustrates an embodiment of an energy storage system on-board a recreational vehicle or van. In this system application, a process-configuration of the pCDE module performs the main storage and conversion processes. A process-configuration of the pD module acts as a smart distribution fuse panel for the subcircuits within the vehicle, denoted by L1 through Ln. In this figure, the double line represents the data interconnect. One dotted line represents the power interconnect attached to solar panels. The other dotted line represents the power interconnect attached to the car's alternator/battery. The solid line represents the power interconnect which interfaces with grid power.

FIGS. 8A-8C illustrate embodiments of residential and commercial energy storage. FIG. 8A illustrates an embodiment of a grid-tied photovoltaic system with energy storage. This embodiment of the system application is constructed using pCDE modules. FIG. 8B illustrates another embodiment of the system of FIG. 8A augmented using a pD module for breaker box distribution. This allows the breaker box to be accessed and controlled remotely. FIG. 8C illustrates another embodiment of the system of FIG. 8B, but with the meter replaced by a p module. This enables a new way to monitor metering. In these figures, the double line represents the data interconnect, the dark solid line represents the DC power interconnect, and the dotted line represents the AC power interconnect.

FIG. 9 is a top plan view of a pCD module consistent with implementations of the current subject matter.

FIG. 10 is a top perspective view of the pCD module of FIG. 9.

FIG. 11 is a rear perspective view of the pCD module of FIG. 9.

### DETAILED DESCRIPTION

Described herein is an architecture for modular electrical utility systems that perform storage, conversion, and/or distribution of electrical energy. These systems manage electrical energy from and across its lifecycle of production, storage and consumption. Current state-of-the-art systems have limitations which arise from their focus on modular subsystems. The architecture provided herein takes a systems-level approach to modular electrical utility systems, providing a comprehensive and integrative (complete and scalable) architecture for managing electrical energy throughout its lifecycle from production to consumption that works across a broad range of applications. Specifically, this architecture provides the means through which the generalized compute power, as well as the conversion, storage, and distribution of electrical energy may be increased modularly to scale up the specific processes to meet the demands of varying applications.

The architecture provided herein takes a systems-level approach to modular electrical energy utilization. On a broad level, there are four specific processes which may comprise these systems: 1) generalized computation, 2) electrical conversion, 3) energy storage, and 4) electrical distribution. The proposed system enables all processes of electrical energy utilization to increase modularly as desired, lending itself to a diverse range of applications. Furthermore, this architecture can contain multiple separate electrical busses such as direct current (DC) busses, alternating current (AC) busses, or generalized power busses and can be interfaced with through logic signals, enabling compatibility with a multitude of input and output devices.

The flexibility in system configuration gives this architecture three distinct characteristics. With input power from both AC and DC sources, this system can source electrical energy from a variety of generators. For this reason, the architecture is considered source agnostic. In the same way, output power in the form of AC, DC or generalized power signals may be achieved, making this architecture load agnostic. Further, the system proposed is independent from the mechanism of energy storage used, so long as this mechanism can interface with the system through electrical signals. Thus, this architecture is also mechanistically energy storage agnostic.

This architecture then represents a truly complete, cohesive and scalable system of electrical energy utilization that is source agnostic, load agnostic, and energy storage agnostic that can dynamically adjust the processes of computation, energy storage, conversion, and distribution. Additionally, this system can support a variety of input and output devices, enhancing the ability to create intuitive and useful human interfaces. This architecture then provides an unparalleled level of system design flexibility, lending itself to the construction of a diverse range of applications.

Applications requiring the storage, conversion and/or distribution of electrical energy rely on many discrete electronic devices. At the fundamental level, there are four families of devices, referred to herein as “process-devices,” which may comprise such systems: 1) computing devices, 2) conversion devices, 3) distribution devices and 4) storage devices. These process-device families relate directly to the processes which they support. For example, computing devices aid generalized computation, conversion devices aid electrical conversion, distribution devices aid electrical distribution, and energy storage devices aid energy storage. Additionally, in modular or dispersed architectures there is a desire to interface between modules via interconnects. Finally, these systems rely on a multitude of peripheral devices such as input output devices or prime movers.

To understand the architecture provided herein, it is useful to define these four families of process-devices and their configurations as they pertain to both the modules and the system of modules presented herein. Furthermore, it is useful to define the interconnects which integrate the modules to form the system. We define herein the four families of process-devices, the interconnects and the peripheral devices. From here, we demonstrate how these process-devices can be integrated to construct the modules encapsulated by this patent. Then, we describe how these modules can interface with each other via interconnects to form the system that is the Integrative Architecture for Modular Electrical Utilization (IAMEU). Finally, we describe key characteristics of this architecture.

The architecture described herein may be realized in a variety of physical constructions. The modules themselves, their interconnects, the internal data and system data communicated between them, the system which they form, and the various ways they can be deployed to perform their function, all have unique embodiments. In the Examples provided herein, some exemplary embodiments for the aforementioned subjects will be described.

As used herein, the term “storage devices” or “energy storage devices” refers to any device capable of storing energy that can then be interfaced with through electrical signals. These devices can take on a wide range of diversity. For example, these devices may be realized through any combination of: electromechanical elements, such as a motor, pump, or generator; electrochemical elements, like a battery; electrical elements, such as capacitors, supercapacitors, inductors, transformers or any type of inductive or capacitive device intended to store electrical energy. Examples of some of these combined energy storage devices include grid scale storage devices such as pumped hydroelectricity, compressed air, batteries, flow batteries, molten-state batteries, flywheels, superconducting magnetic energy, thermal, and solid mass gravitational potential energy. Furthermore, these devices may contain an internal management system such that their operation is controlled without help from additional compute devices.

As used herein, the term “conversion devices” refers to those devices which cover all forms of electrical energy conversion, such as DC-to-DC, DC-to-AC (inversion), AC-to-DC (rectification), and AC-to-AC converters. Broadly speaking, this category covers devices intended to change the current and/or voltage characteristics of the input power. Thus, transformers and filters are considered conversions devices under this definition. These devices may provide electrical isolation and may be capable of bidirectional power transfer. These conversion devices may be controlled externally by a processing device. Alternatively, the conversion devices may contain built in control methods which require no external processing device. An example of this is a DC-to-DC converter with a built-in sensing network, ramp generator, compensation network and comparator forming a PWM generator with closed-loop feedback in order to properly control the converters operation.

As used herein, the term “distribution devices” refers to devices that control the flow of electrical energy through the system. These devices create transfer networks which allow the dynamic distribution of power flow at the input, intermediary and output stages of a system. They provide circuit protection, load and/or source sharing. These can take the form of isolators, circuit breakers, fuses, switches, switchgear, multiplexers, demultiplexers, conductors like common or private electrical busses or any sort of device intended to control the flow of electrical energy through the system. A distribution device may even take the form of capacitors and reactors intended to balance reactive energy present in non-unity power factor loads.

As used herein, the terms “computing devices,” “compute devices”, “processing devices,” or “compute unit,” all refer to devices consisting of at least one control/processing unit required for monitoring and controlling module operation while carrying out communications within each module in the system. Compute devices encapsulate the components to monitor and control the module operation such as any sensors that are internal to the module itself. Furthermore, the processing device(s) may have a generalized compute platform capable of interfacing with common input/output devices, rendering it useful for many IoT and information applications (such as bitcoin mining, database management, etc.). Examples of computing devices include any microelectronic, quantum or photonic processors, microprocessors, FPGAs, DSPs, motherboards, data buffers, ADCs, DACs, and data storage such as RAM, SSD, etc.

As used herein, the term “interconnects” refers to objects or devices that provide the links between modules to transfer information and/or power signals. These interconnects may transmit the required signals through wired and/or wireless connections. Wireless transmission methods include inductive, capacitive, or electromagnetic radiative techniques. Wired transmission methods include fiber optics, electric cabling of varying length, cross sectional area, construction and material, as well as integrated connections via chip-to-chip interfaces.

As used herein, the term “peripheral devices” refers to those devices which connect the system to its environment. These include general input/output devices like displays, buttons, switches, keyboards, mice, trackpads, speakers, knobs, etc. They also include those devices which perform measurement and produce the signals which are used by the computing device. For example, current sensors, voltage sensors, temperature sensors, motion sensors, humidity sensors, electromagnetic radiation sensors, or any other device intended to measure various parameters about the system or the system's environment. Peripheral devices also include prime movers such as motors, generators, actuators, ion thrusters, or any device intended to convert electrical energy to mechanical energy or vice versa.

I. The Modules and the System of Modules

Here we show each module to contain a compute device capable of communicating information pertaining to both its internal state and the system's state. Furthermore, these modules interface through interconnects in order to form the structure of the combined system. These modules then inherently contain a processing device and can interface with the interconnects to form the system of modules. Since a compute device is included in each module, our focus is on the remaining three process-device families and how they are combined to form the unique modules which comprise this system. Under this definition, a module has a compute device, an interface to interconnects and some combination of the remaining process-devices.

The Eight Module Types

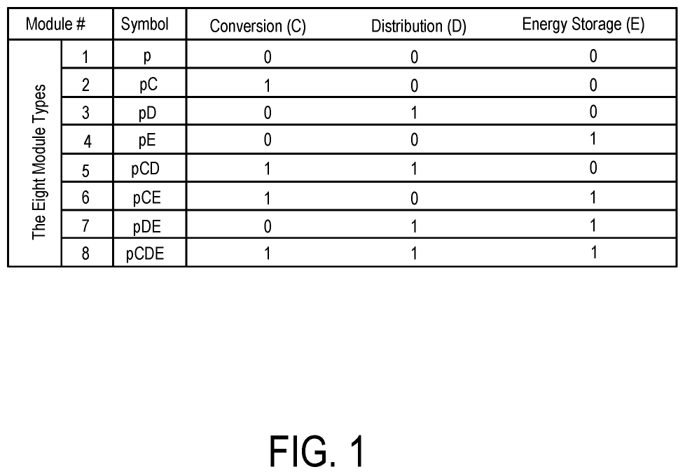

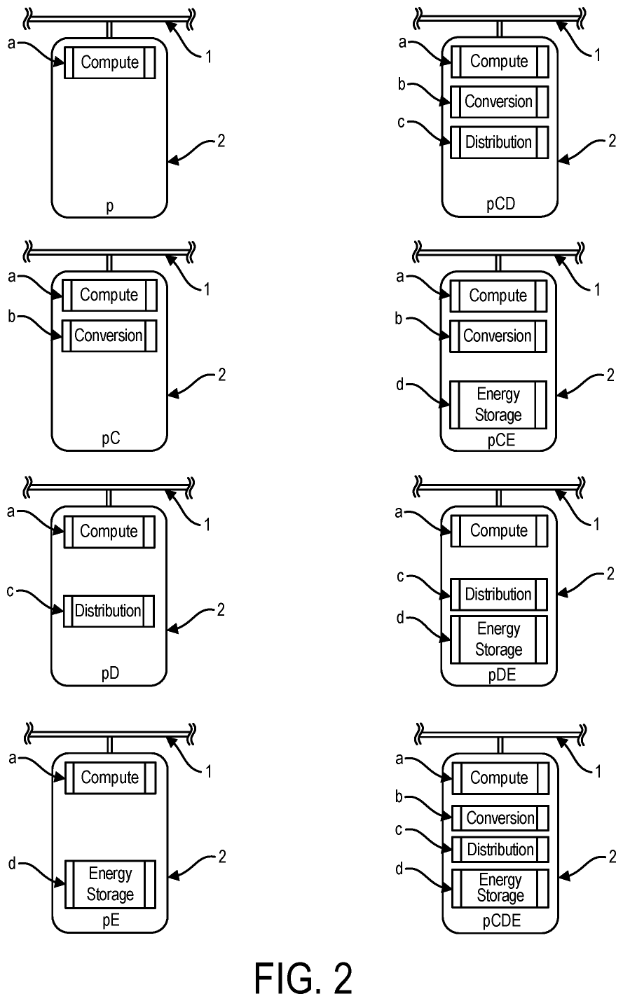

FIG. 1 shows eight possible combinations of the remaining process-devices, namely the conversion, distribution, and energy storage devices. These modules and their various configurations are the constituents which comprise this integrative architecture. We refer to each module by use of shorthand symbols that represent the underlying processes contained in each module. A lower case p denotes the compute process innate to each module. We use the capital letters C, D, and E to denote the optional conversion, distribution, and energy storage processes, respectively. FIG. 2 shows the layout for each of the eight module types. In these figures, the numeral 1 marks the shared interconnect to integrate all the modules into a system. The module boundary is marked by the numeral 2. This is not a physical boundary, rather a conceptual boundary to define the scope of the module. Finally, letters a through d mark the four processes of compute, conversion, distribution and energy storage, respectively. These processes are constructed through any combination of the process-devices.

The p module contains no energy storage, distribution or conversion devices. It contains the computing devices and the required system interconnects to perform the desired compute process. At its core, the p module is fundamentally a modular compute device. One example of this module is an add-on compute capacity capable of carrying out any number of functions such as specialized data processing, added memory storage, increased I/O count to the system, augmented general compute power, or even simply as a redundancy mechanism for the system.

The pC module contains conversion devices in addition to the inherent compute devices and interconnects. An example of this module would be a stackable inverter which can interface to an external energy storage device or input power source. When stacked, the pC module increases the power ratings for certain conversion processes dependent upon the type of converter(s) implemented. Furthermore, there may exist multiple conversion devices in a single module such that when stacked it increases power capability in more than one process.

The pD module has just distribution devices. This seemingly simple module enables greater flexibility in system design. Specifically, the pD module aids in the intelligent control of system dynamics. Since each of these distribution modules will contain a compute device, these modules may effectively respond to the system environment. This provides programmability built into system distribution.

The pE module may comprise energy storage devices. An example would be a lithium-ion battery pack with internal BMS. However, the mechanism of energy storage may take on any form such as pumped-hydro, geothermal, etc. When stacked, the pE modules increase the energy storage capacity of a system.

The pCD module combines both conversion and distribution devices. One example would be a modular DC/DC converter connected to an electrically resettable circuit breaker. In this way, this module performs both power conversion and circuit protection simultaneously. The pCD module then combines the utility of the pC and pD modules.

The pCE module comprises both conversion and energy storage devices. An example would be a lithium-ion battery-pack with internal BMS connected to a bidirectional DC/AC inverter-rectifier. These modules can be stacked to augment both the energy storage capacity as well as input and/or output power ratings. The pCE module then combines the utility of the pC and pE modules.

The pDE module joins distribution devices and energy storage devices. An example of this module is a lithium-ion battery-pack with internal BMS connected to a relay that can isolate between multiple input sources and/or output loads. This allows the same battery pack to have multiple different input sources and/or output loads which it can dynamically select between. Furthermore, the internal distribution devices may provide circuit protection. The pDE module then combines the utility of the pD and pE modules.

The pCDE module contains all three families of process devices: conversion, distribution, and energy storage devices. This all-in-one module increases the energy storage capacity and peak power capability of the system while enhancing the system's ability to interface effectively with various input sources and output loads. The pCDE module then combines the utility of the pC, pD and pE modules.

The System of Modules

To be considered a module within the system, it can have a computing device capable of communicating information pertaining to its internal state as well as the system state. Furthermore, the modules connect with the other modules in the system via interconnects. The system can be the sum connection of modules who share, at a minimum, a communication interconnect such that data transfer of internal state and system state is possible. The system accomplishes one of the four processes using at least one module. This means, it is possible to consider a single module a system unto itself, so long as it has the required interoperability with modules in this architecture.

Thus, this architecture can communicate with and thus operate within a larger system of modules. This communication can comprise information signals such that each module may communicate with other modules in the system. The modules communicate their internal state to the other modules in the system, while storing the system state of the connected modules.

Internal state comprises key data to determine the operating condition of the module. System state includes the information required to determine the operation of the other modules within the system. The level of detail of the internal state information is such that the module can be recovered from a fault or other event to a specified level of operation. The level of detail of the system state information is such that the system may recover to a specified level of operation, so long as one module contains this system state information. In this way, every module within the system understands what the other modules are doing to a level of detail such that it can restore the other modules to a desired level of operation. Furthermore, the types of connections implemented, and information transmitted from these interconnects may be used to facilitate a range of communication protocol topologies, state machines or control techniques required for system operation or simple data transfer between each module.

The above eight modules may be combined with other modules of the same type and/or with other modules of a different type. Each module's operational ability may be dependent on or independent from the other modules in the system such that specific or generalized configurations may be achieved. The system is the combined functionality of the module(s) which create it. The system can know the state of every module within the system and may be capable of informing these modules of their previous states after a fault or other event. Thus, the system may recover from and dynamically adapt to a fault condition, or the removal/addition of a module from the system. The system thus enables a cohesive interface through which these modules may combine in order to meet the demands of the required application.

II. Architectural Characteristics

As stated previously, this system is indifferent to the method of power generation, mechanism of energy storage, or type of load. This means the system is source agnostic as defined by its ability to source energy from a variety of power producing devices, energy storage agnostic as defined by its ability to interface with a variety of storage mechanisms to facilitate the delay in the delivery of power, and load agnostic as defined by its ability to provide the power signals to the load, be them AC, DC or some combination of the two. If a single module did not provide these characteristics on its own, in combination with other modules in this patent, these characteristics may be achieved.

This system can then interface with any sort of electrical generation devices such as turbines, solar panels, alternators, grid power, gas generator, wave power, fuel cells, or any other mechanism of power production. This system can store energy in any form including using gravitational potential energy, chemical potential energy, or momentum and can thus take advantage of the wide range of energy storage technologies. Further, the system can power any type of load, whether it be AC, DC or a combination of both AC and DC devices regardless of the application. These load devices may range from DC motors, AC induction motors, linear motors, stepper motors, servo motors, compressors, electric arcs, pumps, to lighting, power supplies for common appliances, and peripheral power for GPIO devices.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

### EXAMPLES

### Example 1: Embodiments of the Modules

Each of the modules may have a multitude of configurations for each process function which it contains. They are referred to herein as process configurations. Each of these process configurations represents an embodiment of one of the eight modules presented herein. This means each module has many different process configurations and thus embodiments. The varying process configurations for each module are outlined in the following.

Process Configurations

The p module can perform the compute process. This module can contain any number of computing devices, working separately, in conjunction with one another or some combination of the two. Furthermore, this module may even have modular replacements such that different compute devices may be added to the base module. An example of this would be extra PCIe slots for added processing power or data storage. Furthermore, this module may even be able to update its software and hardware for example as on a microcontroller, processor, FPGA, or DSP. This enables dynamic adjustments and incremental improvements after deployment.

The pC module can perform the conversion and compute processes. This module may contain any configuration of compute devices as specified by the process configurations of the p module, in addition to a multitude of process configurations for conversion of electrical energy. In the pC module, the conversion process may consist of any combination, but at least one, of the conversion devices. These devices may work separately, in conjunction with one another or a combination of the two. These devices may contain multiple input and output power interconnects but at least one of each or a bidirectional power interconnect. Furthermore, these conversion devices may be controlled by the compute devices within the module or by another method of control.

The pD module can perform the distribution and compute processes. This module may contain any configuration of compute devices as specified by the process configurations of the p module in addition to various process configurations for distribution of electricity. In this module, the distribution process may consist of any combination but at least one of the distribution devices. These devices may work together, separately or a combination of these two. They may contain many input and output power interconnects but at least one of each or a bidirectional power interconnect. Furthermore, these devices may be passive or actively controlled by the compute devices within the unit.

The pE module can perform the energy storage and compute processes. This module may contain any configuration of compute devices as specified by the process configurations of the p module as well as various process configurations for energy storage. In this module, the energy storage process may consist of any combination but at least one of the energy storage devices. These devices may work together, separately or a combination of these two. They may contain many input and output power interconnects but at least one of each or a bidirectional power interconnect. Furthermore, the compute unit within the module may control the energy storage device or the device may have a built-in control mechanism.

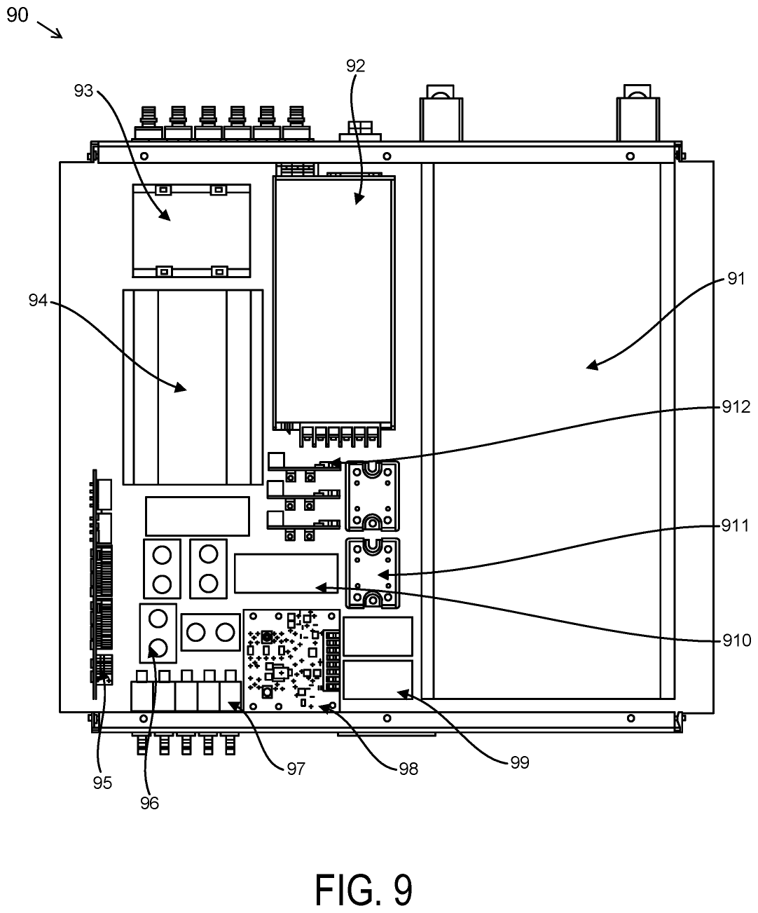

The pCD module can perform the compute, conversion, and distribution processes. This module may contain any configuration of compute devices, conversion devices and distribution devices as specified by the process configurations of the p, pC, and pD modules, respectively. This module also contains any combined configurations of compute, conversion and/or distribution devices. Furthermore, each of the devices may work in conjunction with each other or separately from each other or some combination of these. They may contain many input and output power interconnects but at least one of each or a bidirectional power interconnect. One embodiment of this module is shown in FIGS. 9-11. The module depicted in these figures is intended to interface between AC and DC input sources and output loads while interfacing with an external battery for energy storage. This module contains compute, distribution and conversion devices but does not contain an internal energy storage device and is thus considered a pCD module.

FIG. 9 illustrates an example of an embodiment of a pCD module 90 from the top down. In this figure, the outer housing of the pCD module 90 is not shown, to expose and illustrate the internal components. The pCD module 90 contains four conversion devices: the numeral 91 marks an inverter, the numeral 92 marks a Power Factor Correction AC-to-DC synchronous rectifier, the numeral 93 marks a DC-to-DC output converter, and finally the numeral 94 marks a DC-to-DC maximum power point tracking solar charge controller. There are also several distribution devices in this module: the numeral 96 marks one of multiple (e.g. four as shown in FIG. 9) shunt resistors. The numeral 97 marks one of multiple (e.g. five as shown in FIG. 9) breakers. The numeral 8 marks one of multiple (e.g. two) solid state high-side DC switches, as shown in FIG. 9. The numeral 99 marks one of multiple (e.g. two as shown in FIG. 9) 2-position terminal blocks. The numeral 910 marks one of multiple (e.g. two as shown in FIG. 9) 4-position terminal blocks, and the numeral 911 marks one of multiple (e.g. two as shown in FIG. 9) AC switches. The pCD module 90 also contains a processing device, marked by the numeral 95, which controls the operation of all conversion and distribution devices in the system of modules, as well as communicates with peripheral devices. The numeral 912 marks one of multiple (e.g. three as shown in FIG. 9) AC current sensors which acts as additional processing devices intended to sense the internal current of the AC lines of the modules. Parts 91-94 as described above are all considered conversion devices. Parts 96-911 as described above are all considered distribution devices.

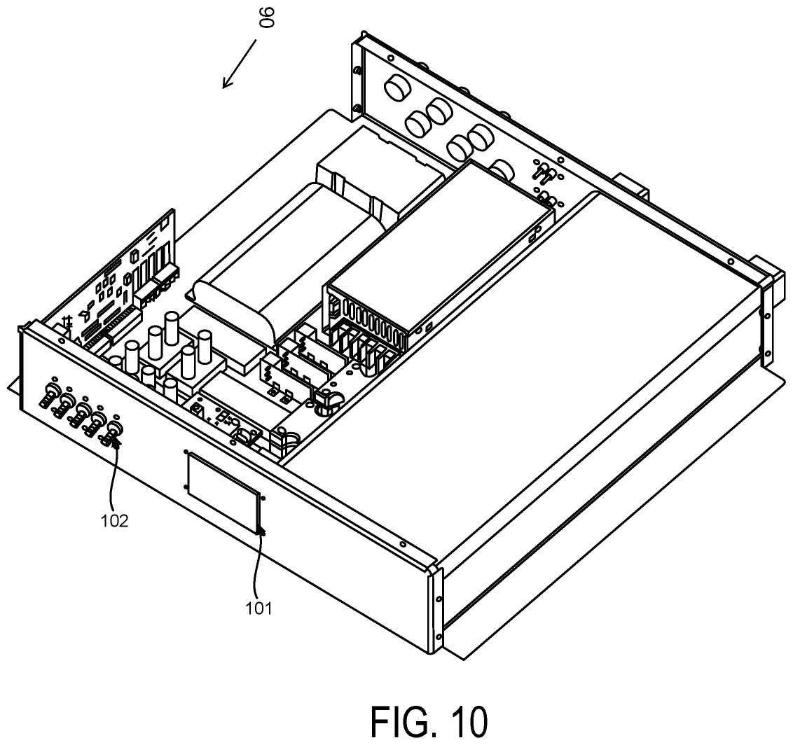

FIG. 10 illustrates the same embodiment of a pCD module 90 depicted in FIG. 9 from an isometric perspective. In this figure, additional peripheral devices are shown. Specifically, the numeral 101 indicates a user interface, such as a touchscreen LCD as shown in FIG. 10, which allows a user to interact with the pCD module 90; and the numeral 102 indicates switches which control the reset on the breakers inside the pCD module 90.

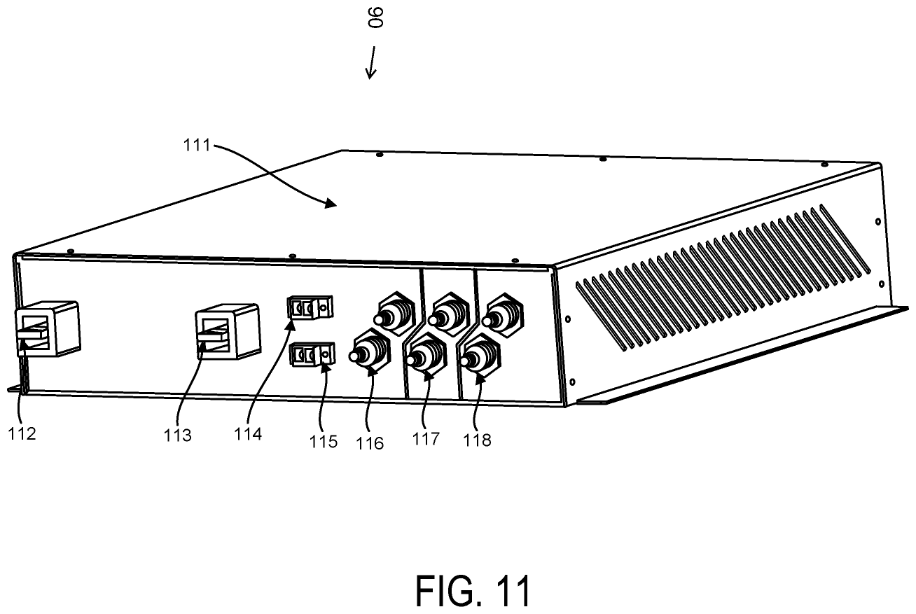

FIG. 11 illustrates the same embodiment of a pCD module 90 depicted in FIG. 9 oriented such that the rear of the pCD module 90 is visible. In FIG. 11, the top of the outer housing 111 is also shown, to demonstrate what the pCD module 90 looks like with the outer housing 111 in place. The top part of the outer housing is marked by the numeral 111. The numerals 112 and 113 mark the positive and negative terminals, respectively, of the interface of the pCD module 90 to an external battery. The numerals 114 and 115 mark the input and output terminal blocks, respectively for the AC lines (not shown). The numeral 116 marks one of the multiple (e.g. two as shown in FIG. 11) terminals for a solar panel input. The numeral 117 marks one of multiple (e.g. two as shown in FIG. 11) terminals for the DC output. The numeral 118 marks one of the multiple (e.g. two as shown in FIG. 11) terminals for input from an additional 12V source, such as a car alternator. Parts 112 through 118 as described above are all considered distribution devices as they are configured to control the flow of energy into and out of the pCD module 90.

The pCE module can perform the compute, conversion, and energy storage processes. This module may contain any configuration of compute devices, conversion devices and energy storage devices as specified by the process configurations of the p, pC and pE modules, respectively. This module also contains any combined configurations of compute, conversion and energy storage devices. Furthermore, each of the devices may work in conjunction with each other or separately from each other or some combination of these. They may contain many input and output power interconnects but at least one of each or a bidirectional power interconnect.

The pDE module can perform the compute, distribution, and energy storage processes. This module may contain any configuration of compute devices, distribution devices and energy storage devices as specified by the process configurations of the p, pD, and pE modules, respectively. This module also contains any combined configurations of compute, distribution and energy storage devices. Furthermore, each of the devices may work in conjunction with each other or separately from each other or some combination of these. They may contain many input and output power interconnects but at least one of each or a bidirectional power interconnect.

The pCDE module can perform the compute, conversion, distribution, and energy storage processes. This module may contain any configuration of compute devices, conversion, distribution devices and energy storage devices as specified by the process configurations of the p, pC, pD and pE modules, respectively. This module also contains any combined configurations of compute, conversion, distribution and energy storage devices. Furthermore, each of the devices may work in conjunction with each other or separately from each other or some combination of these. They may contain many input and output power interconnects but at least one of each or a bidirectional power interconnect.

Peripheral Devices

Each of the modules discussed may be connected to peripheral devices through a wired and/or wireless connection. The addition of input/output (I/O) devices such as a built in LCD screen, an on/off button, or even simple indicator lights can enhance user interaction with the module and system of modules. In one embodiment, the I/O devices are built into the module itself such that a unique user interface is available. Furthermore, peripheral devices such as external sensors may be employed to provide the system with enhanced environmental awareness and thus increased functionality. For example, one may choose to add irradiance sensors to a photovoltaic deployment in order to aid in sun tracking for an enhanced maximum power point tracking technique.

Each module may also be connected to prime movers. In one embodiment of the architecture described herein, a module may contain a built-in prime mover such as an actuator or motor. This enables direct interface to mechanical power. For example, a pCDE module may contain a built-in prime mover such that a simple deployment of motive power may be achieved. An example of this would be a pCDE module with a built-in electric motor for use in deployment of electric vehicles.

Furthermore, the modules may be designed for replaceable process devices. This would enable modules of a certain type to be built to a desired specification. In one embodiment of the pC module, there exists a DC-to-DC converter for maximum power point tracking of photovoltaics, followed by an inverter for AC output. In this embodiment, both the DC to DC convert and the DC to AC inverter may be replaced by a corresponding converter of a desired specification. In this way, both the input and output power handling capabilities may be chosen for any specific module. The same may be true of other processes in other modules. For example, a replaceable battery in a module which contains energy storage devices may be achieved.

### Example 2: Embodiments of the Interconnects

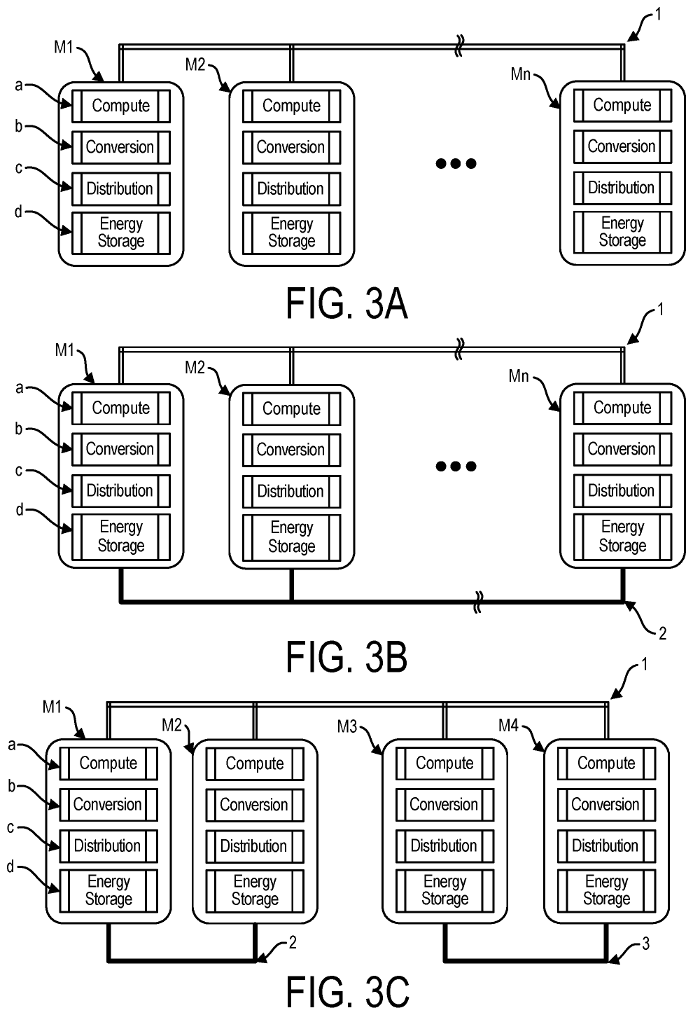

The interconnects are comprised of data connections as well as power connections. The interconnects may be comprised of purely data interconnects or both data and power interconnects. FIG. 3 demonstrates this point. In FIG. 3A, the numeral 1 marks the required data interconnect, whereas in FIG. 3B, the numeral 2 marks the optional power interconnect. The modules in the system are marked by M1, M2 and Mn, with Mn denoting the nth module connected to the system. The letter a marks the required compute device in each module, whereas letters b, c, and d mark the remaining optional process devices. These interconnect diagrams do not capture the physical connection scheme.

Realization of the Interconnects

The data interconnect may take the form of a wired and/or wireless connection. Wired data interconnects may be in the form of a daisy-chain or series connection, a parallel connection in which all modules are connected to a shared data line, or a ring connection in which that last module in a daisy-chain connection is routed back to the first module. Wireless data interconnects may consist of single or multi-channel communication connections to facilitate the data transfer. Furthermore, the data interconnect may consist of any number of and any combinations of the aforementioned connection types.

The power interconnect may also be either wired or wireless. Wireless power transfer techniques such as capacitive and inductive power transfer is possible. The power interconnects may take the form of series or parallel connections. The power interconnects may even consist of a combination of such connections.

FIG. 3C demonstrates a system that comprises two subgroups of electrically isolated systems yet operating as part of a larger system. Here, the data interconnects and the power interconnects are drawn separately to clearly display the system structure. The numeral 1 marks the data interconnect(s) whereas numerals 2 and 3 mark the two separate power interconnects of the system. In this way, it is possible to coordinate subsystems such that they can integrate easily to form the larger system. Furthermore, there can be more than one power interconnect connected between modules. For example, there can exist both AC and DC power busses connected between multiple modules.

Protocol-Specific Interconnects

In one embodiment of a data interconnect, the communication protocol performed through these lines may be one in which there is no designated master. Instead, each module participates as a node in this protocol. A synchronization scheme is implemented on the shared line, allowing each module to share its internal state to the shared line with no conflicts. Furthermore, the daisy chain structure is used to ensure the existence and status of neighboring modules.

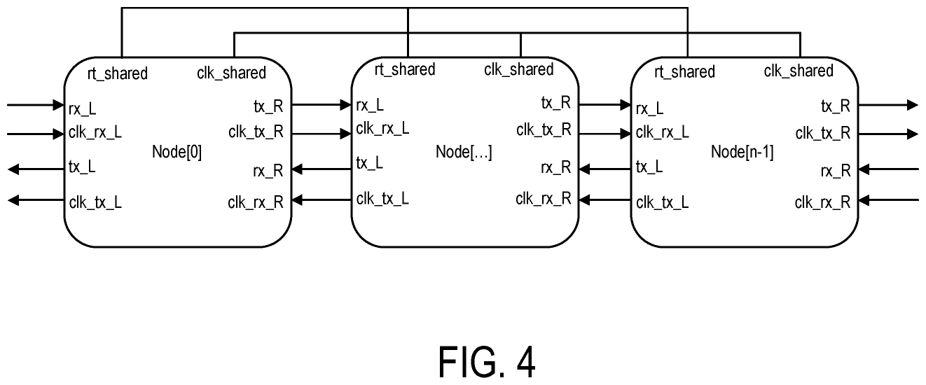

The physical interconnects required by this Masterless System Synchronization (MaSS) protocol are shown in FIG. 4. In this embodiment, each node comprises five main functional units: a transmit right and a receive right, a transmit left and a receive left, as well as a shared transmit/receive line. Each unit is accompanied by a dedicated clock signal for synchronous communication.

In this embodiment, each node can be combined randomly in any order. Therefore, each node has the same codebase for performing this communication protocol. That is, each node is equivalent to the others in terms of the implemented communication logic and is fully capable of playing any role as required by the protocol. This masterless approach to system synchronization yields a generalized procedure for communication.

The proposed protocol is as follows. The startup phase comprises a System Idle and Count-Off procedure in which each node checks if any neighboring nodes exist. There are four cases in total. In the case of No Neighbors, the node is in a Solo Operation State and the main function of the node is initiated. In the case of A Neighbor on the Right, the node updates its list position as 0 and transmits position+1 (1) to the right. Afterward, it awaits the total node count on the shared line. This situation is termed Leftmost Operation State. In the case of Neighbors on Both Sides, the node waits for a node count from the left neighbor. Once it receives this count, it updates its list position as the count and transmits position+1 to the right. Afterward, it awaits the total node count on the shared line. This is the Middle Operation State. Finally, in the case of A Neighbor on the Left, the node waits for a node count from its left neighbor. Once it receives this count, it updates its list position as the count and transmits position+1 to the shared line. This is the Rightmost Operation State. After this procedure completes, the system has the total node count, n, as well as its position in the node list. With these two parameters, the system is ready for shared transmit and receive.

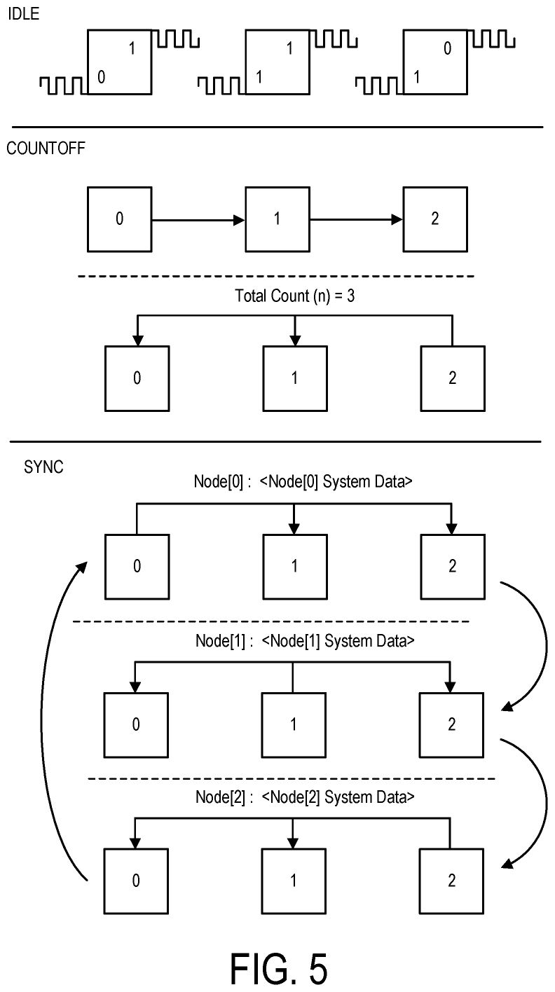

The next phase comprises a Synchronization Process in which each node begins to share its internal state to the shared line. Nodes [1: n−1] await the data frame from node[0]. Node[0] sends the first data frame containing its internal state information. Afterward, node[1] sends its data frame. Then, node[2] sends its data frame, and so on until the last node, Node[n−1], transmits its data frame, the list repeats, beginning again with node[0]. FIG. 5 provides an overview of this procedure.

At any point during the Synchronization Process, a module may be added, removed, or experience a fault condition. In this case, the neighboring modules will recognize this change and interrupt the system to restart the System Idle and Count-Off procedure. Alternatively, the neighboring modules may attempt some other fault recovery technique.

Mounting-Type Interconnects

Wired interconnects may be connected directly to the module or indirectly through some sort of module mounting system. In one embodiment of the architecture, a system of modules which performs a DC-to-AC conversion process contains two wired power interconnects, one DC input bus and one AC output bus, as well as one wired data interconnect. These modules are intended to electrically connect to each other in parallel. In this embodiment of the modules exists a blade type connector for both the power and data interconnects which connects to a module mount. This mount contains the complimentary blade connector for both the power and data interconnects and can connect to other mounts of the same type. Furthermore, the mount contains a conductor or a connection point to a conductor intended to form the shared AC and DC power busses between the modules. In doing so, a mount of a specific power capacity may be chosen for a certain application without worrying about the module's individual power handling capability. This mounting system may be used to get around issues of scaling modular systems beyond the capability of the individual modules. For example, the conversion modules in this embodiment may only be able to transfer 100 amps through their blade connectors, but the mounting system contacts this blade connector with a conductor capable of handling larger currents. In this way, the scaling issue is remedied. When larger currents are desired on the shared bus, a specific mounting system is chosen to accommodate this demand. These mounts may accommodate more than one module at a time. Furthermore, it may be desirable for the mount to provide structural support for the module and system of modules.

Input/Output Frame Interconnects (IO Frames)

For some applications there exists a desire to provide not only the interconnects, but a specific housing structure as well. These housings may provide a structural function in addition to containing the interconnects, prime movers, and/or peripheral devices for a particular application. These IO Frames work in conjunction with the modules of this system to provide a complete deployment of certain applications. One embodiment of an IO Frame is the structural skeleton of an electric scooter. This IO Frame contains the structure of the scooter, including the wheels, shocks, board, fork and handlebars, in addition to an electric motor, and peripheral devices such as throttle, breaks, lights, and an LCD screen. Finally, this IO Frame contains the interconnects required to interface a module described in this system with the peripheral devices and prime mover. Overall, this concept of an Input/Output Frame Interconnect is an advanced version of a system interconnect which allows the modules to interface with each other as well as peripheral devices and prime movers in order to aid in the deployment of specific applications. I/O Frames can be useful in the deployment of electric transport, machinery, and robotics among other applications.

### Example 3: Embodiments of Internal and System Data

The internal data of the modules and the system data shared between them are the link which forms the larger system. Many embodiments exist for both internal and system data. Moreover, these embodiments do not change the definition of the system. Whatever the form of the internal and system data is, this architecture can provide for the system data to be understood by all modules within the system. This could allow the architecture described herein to interface with third party or external devices.

One embodiment of the internal data may be the voltages, currents, and temperatures within the module itself. The module may use this data to perform monitoring and control, in addition to generating interrupts. The system data received from the other modules may take the form of an interrupt flag, a request, a command, or some other information pertaining to its internal operation such as power output. In a simpler embodiment, the internal data comprises a single bit and system data comprises as many bits as there are modules in the system. This bit may be correlated to an on/off signal. In this simple embodiment, all the modules in this system may still store data about the other modules in the system.

In one embodiment of this architecture, a module which performs energy storage may be connected to another module which performs conversion. In this embodiment, the energy storage module comprises a battery pack formed by multiple battery cells. The internal data for the energy storage module may contain internal data such as the currents, voltages, and temperatures of every individual cell in the pack. The conversion module in this embodiment may be a bidirectional DC-to-DC converter. This conversion module may contain internal data such as voltages and currents of the input and output ports, as well as the temperature of various components within the converter. When these modules are integrated to form the system, they both contain system information about the other. For example, the energy storage module contains system data provided by the conversion module such as power at the input or any fault conditions within the converter that may affect the energy storage process such as a short-circuit failure. On the other hand, the conversion module contains system data provided by the energy storage module such as the state-of-charge or state-of-health of the battery or any fault conditions within the battery.

The communication of system data may be constant, intermittent or even one-time such as a communication protocol handshake which provides the data to the other modules in the system to inform them what processes are contained within the connected module and what sort of power interconnects are available to each module. In this way, every module has some understanding of what other modules exist within the system. These data may then be used to facilitate the validation of certain system configurations to ensure the system is properly connected. This offers a unique approach to system deployment in which the system data shared between the modules can inform the user what connections are possible and which ones have been made.

This can hold this architecture together. For example, in another embodiment of this architecture, a module which performs conversion is attached to a 3rd party energy storage device such as a lithium-ion battery pack with internal BMS. The conversion module in this embodiment may be a bidirectional DC-to-DC converter. This conversion module may contain internal data such as voltages and currents of the input and output ports, as well as the temperature of various components within the converter. While the external battery device may be able to communicate information pertaining to its state-of-charge or state-of-health to the conversion module, the 3rd party device is not capable of receiving the system data from the conversion module. Furthermore, during a failure or some other event within the conversion module(s), the 3rd party external battery device is incapable of restoring the system to a desired level of operation. In this way, the 3rd party device is considered external to the system since it is incapable of the required interoperability. This same line of reason can be used for any sort of 3rd party, conversion, distribution and or energy storage device.

### Example 4: Embodiments of System Applications

In general, electrical utilization systems are used across the broad sectors of commercial, residential, industrial and transportation applications. Regardless of the application, the IAMEU provides the framework for deploying a complete and scalable solution. Aside from the varying embodiments of the eight modules, their interconnects and their internal and system data, the ways in which they can be integrated to perform a certain application may also take on multiple configurations. In this Example, a few of the exemplary embodiments for key applications are outlined.

Electric Vehicles

Due to the load agnosticism of the architecture, a variety of motor drives are available to utilize. This feature lends itself well to electric drivetrains for things such as trains, cars, small electric transport like e-bikes, e-scooters, and e-boards, as well as things as dynamic as drones and quadcopters. This section will cover how some of these applications may be constructed using the IAMEU.

Electric Car

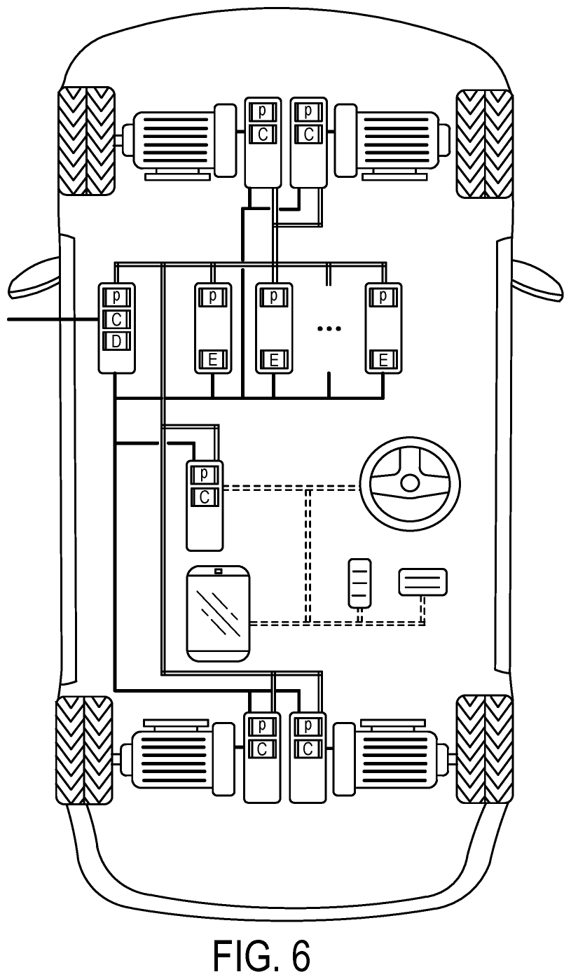

In one embodiment of a drivetrain for an electric vehicle, a pCD module acts as the battery charger and thus interface to the power source for the car's main energy storage modules. The input power flowing from the pCD module charges the main battery set, constructed using as many pE modules as desired for suitable energy storage capacity. The battery modules are then connected to the four motor drives, each constructed using pC modules. The output of these motor drives controls the electric motors present at each of the four tires on this vehicle. Finally, a different process-configuration of the pC module acts as the main compute unit which interfaces with the I/O devices such as the pedals, steering wheel, and main LCD panel which is used to display a GUI for the driver. This system application embodiment is demonstrated in FIG. 6.

In another embodiment of an electric vehicle drivetrain, a pCD module acts as the battery charger and thus interface to the power source for the car's main energy storage modules. The input power flowing from the pCD module charges the main battery set, constructed using as many pE modules as desired for suitable energy storage capacity. Multiple pC modules are used as the main power drive to the vehicle's single electric motor. In this embodiment, the motor drive modules are stackable to provide the power needs for a range of motors. Again, another process-configuration of a pC module can act as the main compute unit which interfaces with the I/O devices such as the pedals, steering wheel, and main LCD panel which is used to display a GUI for the driver. However, in this embodiment there exists a separate battery system intended to supply power for non-drivetrain applications. This secondary battery system is constructed using pCDE modules. The main power interconnect for this secondary battery system is also connected to a pD module which then delivers the power to loads in the vehicle such as appliances, pumps, or compressors. Moreover, the pCDE modules may be attached to a slide mount system such that they can be pulled for use outside the vehicle, enabling mobile energy storage. Although two isolated power interconnect systems exist, all modules are attached to a common data interconnect and are thus apart of a single system.

Electric Scooter and Electric Bike

In simpler embodiments of electric drivetrains, one can make use of only a few modules to complete the system. In one embodiment of an electric scooter, a single pCDE module may contain all the process devices to provide a complete solution. This embodiment of the pCDE module contains a compute device capable of hosting an operating system for the GUI, in addition to interfacing with I/O devices such as the throttle and brake controls and a touchscreen LCD. Furthermore, this pCDE module may be equipped with the compute devices to interface with RF transceivers such that it may be connected to the internet and GPS to provide routing and directions. This module would also have the energy storage device and conversion device used to power the motor on the wheel. This module also contains the distribution devices such as fuses and isolators to ensure safe operation.

A similar embodiment of an electric bike may be constructed by stacking two of the aforementioned pCDE modules together forming a system with twice the energy storage capacity, twice the output power capability and twice the charge capability. Furthermore, the compute devices onboard both modules may work together, determining a tasking system which makes best use of the resources and demands of the operating system and I/O devices.

Electric Quadcopter

In one embodiment of a drone, four pC modules provide power to each motor of a quadcopter. Connected to these drive modules is an embodiment of the pE module which contains the main energy storage devices for the quadcopter and the compute devices to do things such as enable GPS, process audio/video data, and perform any other task such as range finding. This module then also interfaces with I/O devices such as a RF transceiver or a camera sensor. This module is removable such that it can be readily replaced by a module of its type. The charging system for this quadcopter may consist of as many pCD modules as there are desired battery replacements. These modules contain the conversion and distribution devices to take input power from the grid and charge the batteries of the quadcopter. In this example, both the quadcopter and the charging systems are separate systems since they do not share a common data interconnect. In another embodiment of this application, there exists a wireless data interconnect between the charging station and the drone. This data interconnect combines the two systems into one such that they can effectively coordinate to enhance system functionality.

Energy Storage

Another application which the IAMEU lends itself to is energy storage. The applications for energy storage range all the way from consumer level to residential, commercial and utility scale systems.

Recreational Vehicle and Van Energy Storage

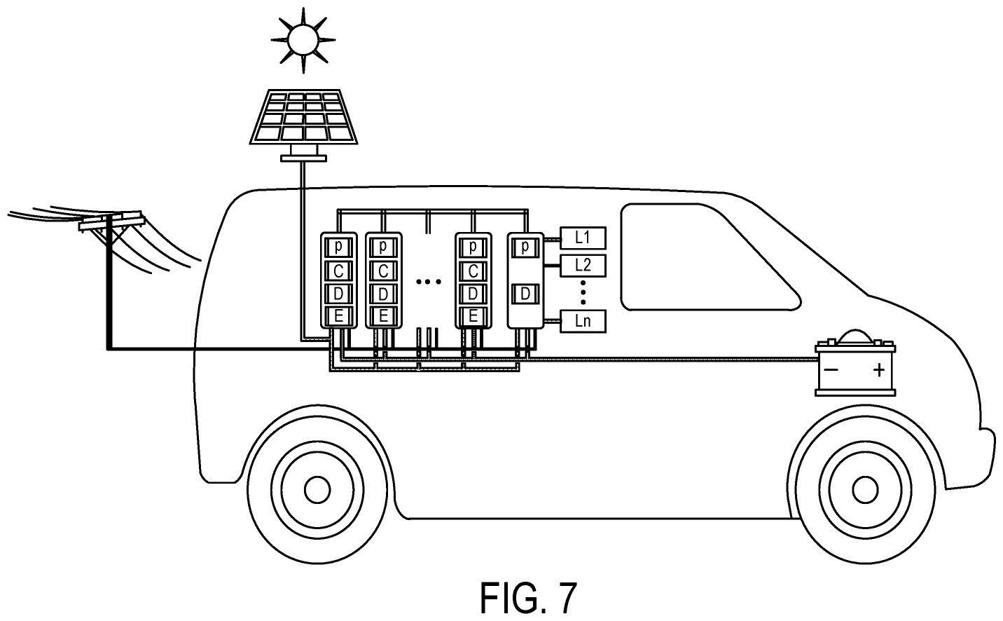

In one embodiment of an energy storage system on-board an RV, shown in FIG. 7, a set of pCDE modules are used to provide a level of power output and energy storage capacity. This embodiment of the pCDE modules contain conversion devices to source power from the car alternator, grid power, and solar panels as well as to provide power to both AC and DC systems. These modules also contain an energy storage device. Thus, these modules can be taken out and used outside the system as portable energy storage. The compute device onboard each module may be capable of hosting an operating system and interfacing with an LCD to provide a GUI with which the user can monitor the system log data.

Residential and Commercial Energy Storage

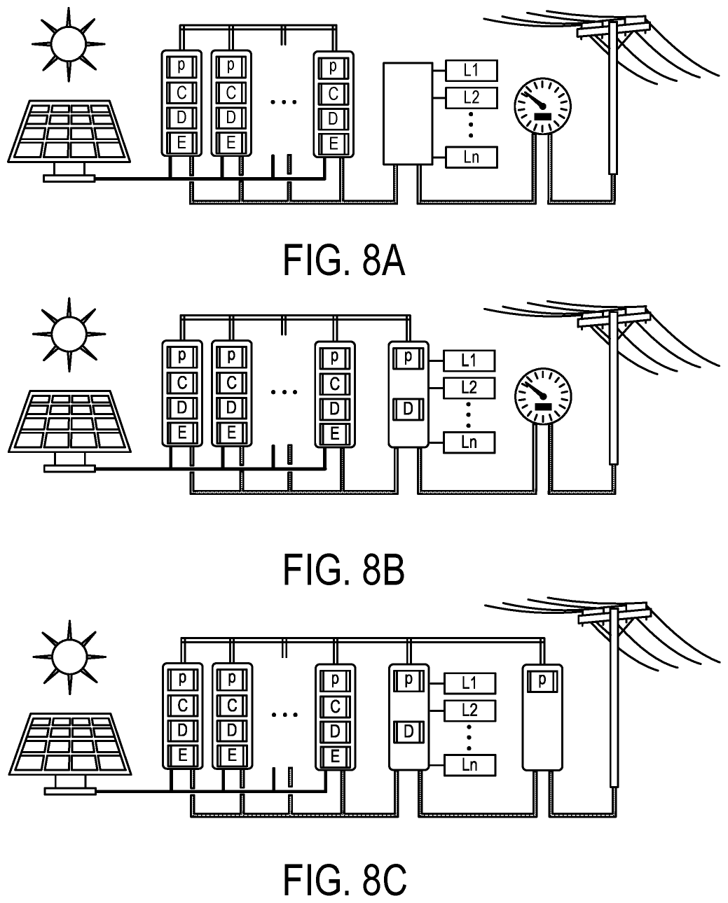

Another embodiment of an energy storage system constructed using the IAMEU can provide energy storage capability to residential and commercial properties. In a simple embodiment of this system, pCDE modules are stacked together to achieve the desired energy storage capacity and power output capability. This embodiment of pCDE module contains the conversion devices to perform maximum power point tracking of the solar panels. Furthermore, these modules provide AC output which connects to a distribution panel that breaks out the various subcircuits in the property. Finally, this AC line is then fed to a meter then to the grid. This then means that the inverter in each module can synchronize its output waveform to that of the grid such that minimal losses occur when connecting to the grid line. Furthermore, the compute device enables wireless connection to the users IoT device such as a cellphone or computer such that the system may be monitored. This embodiment is displayed in FIG. 8A. In another embodiment of this system, shown in FIG. 8B, a pD module is used as the distribution device in place of the distribution panel of the previous embodiment. This module increases the functionality of the system by providing a means to remotely reset the circuit breakers in the system through the GUI. FIG. 8C showcases yet another embodiment of the system where the electric meter is replaced by an embodiment of a p module intended to perform metering. Yet again, functionality of the system is increased by enabling a center point for energy retail markets to operate.

Furthermore, the process-configuration of the pCDE module deployed in FIG. 8 may be the same module as, or compatible with, the pCDE module used in the electric scooter/electric bike examples. In this way, the modules may be mounted in the solar storage system when not in use, then pulled out to be used in the e-scooter/e-bike. This enables reuse of the module for both the solar storage and electric transport applications. This demonstrates how the same module may be used across multiple system applications.

Grid-Scale Energy Storage

Energy storage at grid scale may involve interfacing to a specific mechanism such as pumped hydroelectricity. Since pumped-hydroelectric energy storage may be interfaced with through electric signals, it is considered an energy storage device. In an embodiment employing this form of energy storage contains at its core modules which perform the conversion processes in addition to the distribution processes for protection. One embodiment of the pCD module contains both the distribution and conversion devices to transform the input power to that which is required by the main pump for the hydroelectric storage system. Additionally, this module may also contain the conversion and distribution devices to transform the energy stored in the hydroelectric system to power that is required for the grid. The compute device available on this module may run an operating system such that a plant operator may monitor and control the system. This compute device may interface with external sensors such that it can provide metrics such as water level or power draw from the pump.

In another embodiment of the same application, three separate modules are utilized to perform the conversion and distribution process. One embodiment of pC modules contains the conversion devices to step down the grid-line AC voltage. Another embodiment of the pCD module contains the conversion devices to convert the stepped down voltage to the form required by the main pump for the hydroelectric storage system. Furthermore, this module also contains the conversion and distribution devices to transform the energy received by the hydroelectric storage systems to a form that can then be stepped up to match the grid. Finally, another embodiment of the pC module contains the conversion devices to step up the voltage to meet the grids needs. In this embodiment of the system application, there also exists an embodiment of thep module which adds enhanced compute capability to effectively monitor and control the system in addition to providing RF connection such that this station can be accessible through the internet or satellite communications.

Another embodiment of this system application employs a similar arrangement except with two different and electrically isolated embodiments of the pCD module which has a built-in prime mover. In this system, one embodiment of the pCD module contains the built-in pump and the other embodiment of the pCD module contains the built-in water-turbine. This enables a scalable approach to the total energy storage capacity available in the system by allowing pump and turbine capacity to increase modularly. The conversion and distribution devices within each module are rated high enough to handle the peak power draw from the pump and peak power output from the turbines. In this way, the electronics can be built such as to make best use of the prime mover.

Agriculture/Mining

The IAMEU lends itself useful to many applications within the primary and secondary economic sectors such as agriculture, mining, manufacturing and construction. The architectures load agnosticism makes it useful in deploying various forms of prime movers used in these industries. From stationary equipment to moving machinery, the IAMEU provides solutions for these applications.

Irrigation

One deployment of an irrigation system contains an embodiment of the pCD module to convert the input power source to power pumps, valves, and other components used to control the flow of water through the irrigation system. The compute device on this module may be capable of interfacing with humidity, temperature, light, pH, or soil sensors. Furthermore, the conversion and distribution devices on this module may even provide power for lighting, HVAC, fans and other equipment. Another embodiment of this same system application involves the use of pCD modules to power the irrigation system, and another embodiment of the pCD module intended to provide power for the other loads such as lighting, HVAC, fans and other equipment. In this way, both the irrigation and auxiliary systems may be expanded separately. Finally, one can easily integrate a photovoltaic energy storage plant into this system. In this embodiment, the addition of an embodiment of the pCDE module can be used to interface between the solar panels and the loads of the system. These modules may contain the conversion devices to perform maximum power point tracking of the solar panels, store the required energy, and convert the power to the proper form as desired by the rest of the system. This last embodiment then enables a completely scalable approach to energy production, storage and consumption in context of agriculture and irrigation systems.

Drilling

Another application system which the IAMEU may help enable are those which require powerful prime movers such as mining equipment. In one embodiment of a mining drill drive system, an embodiment of the pCD module is deployed to convert the input power from a generator to provide drive signals to the prime mover which operates the drill. In this case, the prime mover may be a motor of various power ratings or any other type of prime mover to perform the mechanical motion desired in the drilling process.

Electric Arc Furnace

One method used in the production of steel and iron is the Electric Arc Furnace (EAF). One embodiment of the pC module contains the conversion devices to provide power to the electrodes of the furnace. This embodiment of the pC module may stack together with modules of the same type in order to increase the throughput of the EAF. Thus, this module architecture enables a scalable approach to furnaces of this type. Furthermore, in this system application these pC modules may be attached to an embodiment of a pCD module which takes input power from the grid to power the process. Moreover, an embodiment of the pDE module may be employed to add energy storage capability to this system. This may be useful in counteracting the duck curve of utilities companies resulting from the increasing deployment of photovoltaics to the grid—the EAF factory may pull more energy than desired during periods of low utilities output, or periods of maximum solar energy production, and then draw the stored energy from its batteries as the renewables begin to decrease power production and consumers begin to draw more energy from the grid. Finally, an LCD screen or some other form of peripheral devices may be used to monitor and control each aspect of the system, providing total control of the EAF factory.

Heavy Equipment/Machinery

In many applications in the primary and secondary economic sectors, heavy equipment and machinery is required for various reasons. Earth movers, crushing equipment, tractors, cranes, and other machines of the like can all be deployed using the IAMEU. In this system application, a pCDE module which contains the devices to power multiple prime movers such as actuators for hydraulics or motors for drivetrains. This embodiment of the pCDE module may interface with another embodiment of the pE module intended to augment the energy storage capacity of the system application. Finally, IO Frames acting as the structural frame for the various types of heavy equipment may be constructed. A specialized IO Frame is desired for each type of heavy machinery application; however, they have in common the module interfaces desired to connect to these embodiments of the pE and pCDE module. This allows for the reuse of the pE and pCDE in each of these machines. The advantage of this arrangement is that each IO Frame may be developed relatively cheaply since they only contain structural support, peripheral devices, and interconnects, while the generalized modules presented in the IAMEU may be used across each of these IO Frames.

Robotics

Another system application which the IAMEU benefits is robotics for manufacturing. An embodiment of a pCD module contains the conversion and distribution devices to power various prime movers and receive signals from various sensors and peripheral devices. Once more, IO Frames which makeup the physical construction of the robot may be deployed in conjunction with this embodiment of the pCD module which acts as the brains of the system. The pCD module may be programmed to perform tasks specific to each IO Frame. Thus, the same modules may be used at every stage in the manufacturing process, just housed in different IO Frames. Again, this saves engineering and tooling cost when building out a production line. Instead of getting machines which are specialized for their specific tasks, IO frames which contain the structure to perform this task along with the required prime movers and peripheral sensors can be developed relatively cheaply, while the pCD module may be used across each of these IO Frames. The result is a dynamic production line in which the maintenance, and deployment of new systems is made easier by the consolidation of the technical devices into the pCD module.

Power Tools

In this system application, an embodiment of the pCE module may be deployed to provide the power signals to various power tools or fabrication equipment. Again, IO Frames of each specific device may be constructed with little cost. For example, an embodiment of an IO Frame which has a trigger for controlling speed, drill bit attachment/lock, and an electric motor as the prime mover, may interface with this embodiment of the pCE module in order to provide its power. Similarly, IO Frames for various power tools such as saws, routers, grinders, sanders, nail guns, impact wrenches, drills, lathes, presses, and other power tools that interface with this embodiment of the pCE module may also be constructed. Thus, the pCE module in this example may be used in each of these IO Frames. Furthermore, these pCE modules may interface with an embodiment of a pCD module which acts as a charging bank. This embodiment of the pCD module contains the conversion and distribution devices to convert input power from the grid or an on-site generator, to charge the pCE modules used in each IO Frame. This way, a plethora of power tools may be deployed with a system formed by just two modules, the pCE module as a portable power source for each IO Frame, and the pCD module for charging each pCE module.

Welding

Another application in which the IAMEU may be of use is in welding machines. Welding machines employ electric arcs created typically from DC power but also from AC sources. The power ratings for welding machines may change based on the application at hand. In one embodiment of the pCD module, input power from AC sources such as the grid or generator is converted to a high voltage DC bus which can interface with two different embodiments of the pC module. One of these embodiments of the pC module contains a DC-to-DC converter meant for use in DC arc welding. The other embodiment of the pC module contains an DC-to-AC inverter meant for used in AC arc welding. Furthermore, both pC modules may be combined with modules of the same type to increase the power level desired for an application. Thus, a mechanism for welding can be deployed which can accommodate both AC and DC welding of any desired power rating.

Information Technology/IoT

Server Systems/Computing Clusters

Deployments of server systems or compute clusters may also be accomplished using the IAMEU. Many server systems including database servers, web servers, application servers, cloud servers, as well as compute clusters used for proof algorithms in blockchains such as proof of work, proof of stake, or proof of authority can all be formed using the IAMEU. An embodiment of the pC module which contains the desired compute capabilities, in addition to the conversion devices desired to interface with the common bus voltage, is used in conjunction with modules of its type in order to scale the compute resources as desired. To power the pC modules, an embodiment of the pCDE module is used which can take in grid power and convert this to a 400V bus while storing excess power as a backup. This 400V bus is then converted by the pC modules to power the compute processes. In many of these applications, downtime is unacceptable and so using multiple pCDE modules can provide redundancy in case of failure, and even a short-term backup in case of loss of power. Overall, this system application is well suited by the IAMEU which enables the deployment of an easily configurable, flexible, and reliable system.

Generalized Personal Computing Platform

For personal computing applications, any of the eight modules may be constructed to offer the compute power to offer basic abilities such as web search or application management. This means, a functional computer may be deployed by connecting the proper peripheral devices such as a keyboard, mouse and monitor. If the demands of the compute application exceed what is available in a single module, another module may be connected to the system to create a distributed computing platform. Furthermore, in special cases in which the user desires to have specific compute capabilities, an embodiment of the p module which contains the desired hardware resources may be added to the system. In this way, a range of personal computing hardware configurations may be achieved by the IAMEU.

Satellite Bus and Payload

Both the satellite bus and payloads may be aided by use of the IAMEU. The bus usually comprises the solar panels, energy storage and distribution networks for the power required by each payload, in addition to providing the structural housing to host those payloads. An embodiment of the pCE module which contains maximum power point tracking for the solar panels, energy storage for excess power generated, and another converter to provide power to the regulated 100V bus. Furthermore, the payloads onboard the satellite may be constructed using the IAMEU. One embodiment of the pCD module converts the input 100V bus to the voltages required by the payload. Furthermore, this embodiment of the pCD module provides protection in case of a bus or payload failure. This embodiment of the pCD module may even contain the compute resources to interface with specialized sensors that perform the primary function of the payload. The IAMEU may be deployed in just the bus or just the payload, in which case it treats the other system as external to itself, however still able to communicate information pertaining to commanding and telemetry. Alternatively, both the bus and the payload(s) may be constructed from the IAMEU, in which case each can recover the other from a fault state based on the system data stored in each module. This latter deployment, in which the bus and payload(s) are a part of the same system provides the additional benefit of redundancy and fault tolerance.

Although a few variations have been described in detail above, other modifications or additions are possible. In particular, further features and/or variations can be provided in addition to those set forth herein. For example, the implementations described above can be directed to various combinations and sub-combinations of the disclosed features and/or combinations and sub-combinations of several further features disclosed above. Similarly, elements located on the front, back, side, top, or bottom of an embodiment or implementation are to be understood as relatively positioned, unless otherwise specified. Other embodiments can be within the scope of the claims.

What is claimed is:

1. An architecture for modular electricity utilization, comprising: one or more modules, wherein each module facilitates a compute process.

2. The architecture of claim 1, wherein one or more modules further comprises an electrical energy conversion process, an electrical energy distribution process, an energy storage process, or a combination thereof.

3. The architecture of claim 1, wherein each of the one or more modules further comprises an interface to an interconnect.

4. The architecture of claim 1, wherein each module of the one or more modules further comprises the ability to communicate information pertaining to the internal state of the module.

5. The architecture of claim 1, wherein one or more modules further comprises: the ability to use any electrical power source or electrical power generating device; the ability to use any energy storage device or energy storage mechanism; the ability to provide alternating current (AC) power signals, direct current (DC) power signals, or a combination of AC and DC power signals.

6. The architecture of claim 1, wherein each of the one or more modules further comprises: built-in peripheral devices, the ability to interface with wired and/or wireless peripheral devices, or a combination thereof.

7. A system of modular electricity utilization comprising: one or more modules, connected by at least one interconnect, wherein each module facilitates a compute process.

8. The system of claim 7, wherein one or more modules further comprises an electrical energy conversion process, an electrical energy distribution process, an energy storage process, or a combination thereof.

9. The system of claim 7, wherein each module of the one or more modules further comprises the ability to communicate information pertaining to the internal state of the module; and wherein each module of the one or more modules further comprises the ability to communicate information pertaining to the state of the system.

10. The system of claim 7, further comprising; the ability to use any electrical power source or electrical power generating device; the ability to use any energy storage device or energy storage mechanism; the ability to provide alternating current (AC) power signals, direct current (DC) power signals, or a combination of AC and DC power signals.

11. A method of electrical power utilization comprising: connecting two or more modules via an interconnect to form a system of modules; connecting the system of modules to an electrical power source or electrical power generating device; connecting the system of modules to an energy storage device or energy storage mechanism; connecting the system of modules to a load, appliance or power sink which utilizes alternating current (AC) power signals, direct current (DC) power signals, or a combination of AC and DC power signals; connecting the system of modules to wired and/or wireless peripheral devices which comprise a user interface; monitoring and/or controlling the system state and/or the internal state of each of the two or more modules via the peripheral devices.

12. The method of claim 11, further comprising an interconnect which provides structural support and/or a mounting mechanism for the two or more modules.

13. The method of claim 12, further comprising built-in peripheral devices to enhance user interface and aid deployment of various system applications.

14. The method of claim 11, further comprising a communication protocol, a state machine, a control technique, data transfer, or a combination thereof, performed via the interconnect.

15. The method of claim 14, wherein the communication protocol, state machine, control technique, data transfer, or combination thereof has no designated master.

16. The method of claim 15, further comprising a process in which each module of the two or more modules shares its internal state with other modules via the interconnect; and wherein each module of the two or more modules may be added, removed, or experience a fault condition at any point during this process.
